(19) United States
(12) Patent Application Publication
(10) Pub. No.: US 2022/0336975 A1
(43) Pub. Date: Oct. 20, 2022

(54) CABLE CONNECTOR, MANUFACTURING METHOD OF THE SAME AND CABLE ASSEMBLY AS WELL AS CIRCUIT BOARD ASSEMBLY

(71) Applicant: CommScope Technologies LLC, Hickory, NC (US)

(72) Inventor: Ligang Wu, Suzhou (CN)

(21) Appl. No.: 17/694,018

(22) Filed: Mar. 14, 2022

(30) Foreign Application Priority Data
Apr. 20, 2021 (CN) 202110422127.2

(51) Int. Cl. H01R 12/51; H01R 12/53; H01R 43/02; H01R 43/048

(52) U.S. Cl. CPC H01R 12/515; H01R 12/53; H01R 43/02; H01R 43/048

(57) ABSTRACT

The present disclosure relates to a cable connector, a cable assembly and a circuit board assembly including the cable connector, and a method for manufacturing the cable connector. The cable connector has a cylindrical base body and a plurality of pins protruding from a first end of the base body, and is configured to be sleeved on the outer conductor of the coaxial cable from a second end opposite to the first end, and be mechanically and electrically connected with the outer conductor. The cable connector is made by forming a connector blank, and the connector blank has: a face for forming the base body, wherein the face has a first edge and a second edge, and the second edge is used for forming the second end; and pins extending from the first edge. The cable connector can be manufactured cost-efficiently and be easily connected with a coaxial cable.

### RELATED APPLICATION

The present application claims priority from and the benefit of Chinese Application No. 202110422127.2, filed Apr. 20, 2021, the disclosure of which is hereby incorporated herein by reference in full.

### FIELD OF THE INVENTION

The present disclosure relates to a cable connector for coaxial cables, a cable assembly comprising the cable connector, a circuit board assembly comprising the cable assembly, and a method for manufacturing the cable connector. The cable connector may be applied to communication technology, especially to base station antennas.

### BACKGROUND OF THE INVENTION

Coaxial cables are widely used in radio frequency communication systems. A typical coaxial cable may include an inner conductor, an outer conductor, a dielectric layer insulating the inner conductor from the outer conductor, and a jacket covering the outer conductor. Cable connectors may be applied to both end sections of coaxial cable, and be mechanically and electrically connected with the outer conductor of coaxial cable. Typically, cable connectors known in practice can be manufactured by die casting and subsequent machining, which is expensive.

### SUMMARY OF THE INVENTION

An object of the present disclosure is to propose a cable connector which can be manufactured cost-effectively. Another object of the present disclosure is to propose a cable assembly including such a cable connector and a method for manufacturing such a cable connector.

A first aspect of the present disclosure relates to a method for manufacturing a cable connector having a cylindrical base body and a plurality of pins protruding from a first end of the base body, which is constructed to be sleeved on and mechanically and electrically connected with the outer conductor of a coaxial cable from a second end opposite to the first end. The method comprises:

providing a connector blank having a face for forming the base body, wherein the face has a first edge and a second edge, and the second edge is used to form the second end; and

constructing a complete cable connector by forming the connector blank, or constructing the main body portion of the cable connector except the pins and then forming the pins by subsequent processing of the main body portion.

In some embodiments, a complete cable connector may be constructed by forming the connector blank, wherein the connector blank has pins protruding from the first edge.

In some embodiments, the processing of the main body portion can be realized by stamping or other processing methods.

In some embodiments, the method may comprise:

providing a connector blank having a torus for forming the base body, wherein the torus has an outer edge as a first edge and an inner edge as a second edge; and

forming the cable connector or the main body portion by stamping the connector blank.

In some embodiments, the connector blank may have slots that extend radially in the torus and are open toward the inner edge. The number of slots may be one or two, for example. The slot may completely penetrate the entire thickness of the torus, or may have a depth that is part of the thickness of the torus.

In some embodiments, the method may comprise:

providing a connector blank having a rectangular face for forming the base body, wherein the rectangular face has a first longitudinal edge as a first edge and a second longitudinal edge as a second edge, and a first transverse edge and a second transverse edge opposite to each other; and

constructing the cable connector or the main body portion by rolling the connector blank, wherein the first transverse edge and the second transverse edge form the longitudinal slot of the base body.

In some embodiments, the number of pins may be 2, 3, 4, 5 or 6.

In some embodiments, the pins are uniformly distributed in the circumferential direction on the first end of the base body.

A second aspect of the present disclosure relates to a cable connector having a cylindrical base body and a plurality of pins protruding from the first end of the base body, wherein the cable connector is configured to be sleeved on an outer conductor of a coaxial cable having an inner conductor and the outer conductor from a second end opposite to the first end, and be mechanically and electrically connected with the outer conductor, and is characterized in that the complete cable connector is made from a connector blank by a forming process, or a main body portion of the cable connector except pins is formed from the connector blank by a forming process, and the pins are formed by subsequent processing of the main body portion: the connector blank has a face for forming the base body, the face has a first edge and a second edge, and the second edge is used for forming the second end.

In some embodiments, a complete cable connector can be constructed by forming the connector blank, wherein the connector blank has pins protruding from the first edge.

In some embodiments, the connector blank may have a torus for forming the base body, the torus has an outer edge as a first edge and an inner edge as a second edge, and the cable connector is made by stamping the connector blank.

In some embodiments, the connector blank may have a rectangular face for forming the base body, the rectangular face having a first longitudinal edge as a first edge and a second longitudinal edge as a second edge, and a first transverse edge and a second transverse edge opposite to each other: the cable connector or the main body portion part is made by rolling the connector blank, wherein the first transverse edge and the second transverse edge form the longitudinal slot of the base body.

A third aspect of the present disclosure relates to a cable assembly comprising:
a coaxial cable comprising:
   a. an inner conductor:
   b. a dielectric layer surrounding the inner conductor on the circumference;
   c. an outer conductor surrounding the dielectric layer on the circumference; and
   d. a sheath surrounding the outer conductor on the circumference; and
a cable connector according to the second aspect of the present disclosure, wherein the sheath of the coaxial cable is peeled off on at least one end section to expose the outer conductor section, and the cable connector is sleeved on the exposed outer conductor section from a second end, and is mechanically and electrically connected with the outer conductor section.

In some embodiments, the cable connector may be connected to the outer conductor section by at least one of crimping and welding.

A fourth aspect of the present disclosure relates to a circuit board assembly comprising a circuit board and a cable assembly according to the third aspect of the present disclosure, wherein the cable connector and the inner conductor are attached to, in particular welded to, the circuit board. In particular the circuit board assembly may be used in a base station antenna.

A fifth aspect of the present disclosure relates to a board assembly for a base station antenna, wherein the board assembly comprises a first circuit board and a second circuit board spaced apart from each other, and the first and second circuit boards are electrically connected by at least one cable assembly according to the third aspect of the present disclosure.

It should be pointed out here that the above-mentioned technical features, the technical features to be mentioned below and the technical features shown separately in the drawings can be arbitrarily combined with each other as long as the combined technical features are not contradictory. All technically feasible feature combinations are technical contents included in the specification.

### DESCRIPTION OF DRAWINGS

Exemplary embodiments of the present disclosure are described below with reference to the drawings. Of them:

FIG. 1 is a perspective view of a cable connector according to the first embodiment of the present disclosure.

FIG. 2 is a plan view of one embodiment of a connector blank for manufacturing the cable connector of FIG. 1.

FIG. 3 is a perspective view of a cable connector according to the second embodiment of the present disclosure.

FIG. 4 is a plan view of one embodiment of a connector blank for manufacturing the cable connector of FIG. 3.

FIG. 5 is a schematic view of a stamping die according to an embodiment, with which cable connectors as shown in FIGS. 1 to 4 can be manufactured.

FIG. 6 is a perspective view of a cable connector according to the third embodiment of the present disclosure.

FIG. 7 is a plan view of one embodiment of a connector blank for manufacturing the cable connector of FIG. 6.

FIG. 8 is a schematic view of a cable assembly according to an embodiment of the present disclosure.

FIG. 9 is an exploded view of the cable assembly of FIG. 8.

FIG. 10 is a schematic view of a board assembly for a base station antenna according to an embodiment of the present disclosure.

### DESCRIPTION OF THE EMBODIMENTS

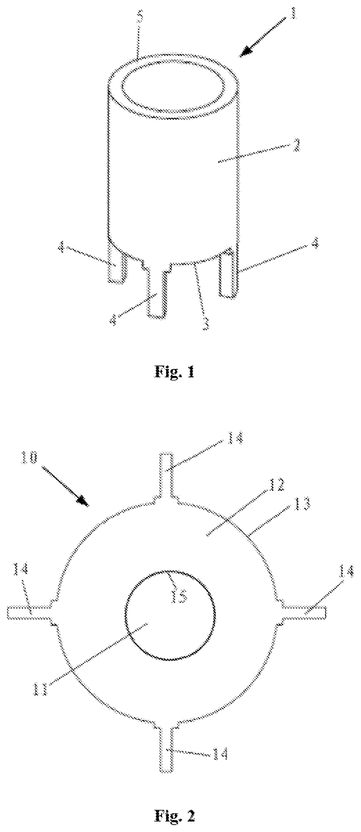

Referring now to FIGS. 1 and 2, an embodiment of a cable connector 1 according to the first embodiment of the present disclosure and a connector blank 10 for manufacturing the cable connector will be described.

As shown in FIG. 1, the cable connector 1 has a cylindrical base body 2 having a first end 3 and a second end 5. Four pins 4 extend from the first end 3 of the base body. Three of the pins are visible in FIG. 1, and the other pin is obscured and therefore not visible. The number of the pins 4 is exemplary and it can be set according to actual needs. The cable connector 1 may be made of metal materials, especially non-magnetic metal materials, such as copper sheet. The metal material should be suitable for the forming process.

The cable connector 1 can be made of the connector blank 10 as shown in FIG. 2 by a forming process, and more specifically, by stamping. The connector blank 10 has a torus 12, and the torus 12 has an outer edge 13 and an inner edge 15. The four pins 14 extend radially outward from the outer edge 13. The inner edge 15 defines a circular central hole 11. Through the stamping process, the torus 12 forms a base body 2 closed on the circumference of the cable connector 1, the pins 14 form the pins 4 of the cable connector 1, the outer edge 13 forms the first end 3 of the cable connector 1 and surrounds the opening defining the first end 3, the inner edge 15 forms the second end 5 of the cable connector 1, and the center hole 11 forms the opening of the second end 5 of the cable connector 1.

In an embodiment of another connector blank not shown, it differs from the connector blank 10 only in that the other connector blank does not have the pins 14, and forms a main body portion of a cable connector without pins 4 after stamping, and that the pins 4 can be subsequently produced in the first end of the main body portion by blanking, machining, or other processing methods.

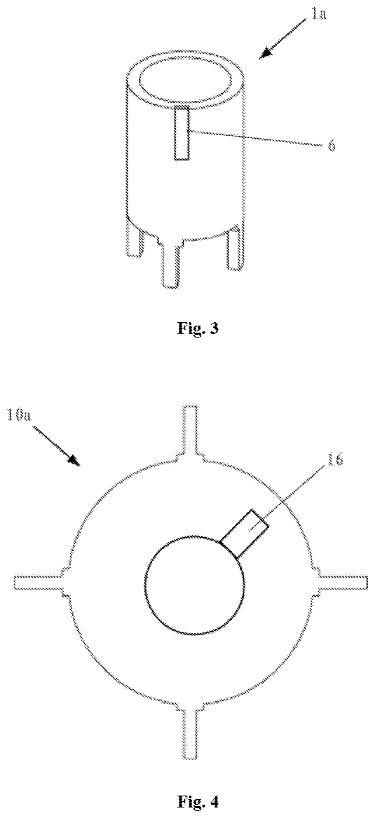

FIG. 3 is a perspective view of a cable connector 1a according to the second embodiment of the present disclosure, and FIG. 4 is a plan view of one embodiment of a connector blank 10a for manufacturing the cable connector 1a. The cable connector 1a differs from the cable connector 1 only in that the cable connector 1a has a slot 6 extending axially in the base body and opening toward the second end. Therefore, the connector blank 10a shown in FIG. 4 differs from the connector blank 10 shown in FIG. 2 only in that the connector blank 10a has a slot 16 extending radially in the annular surface and opening toward the inner edge. The slot 16 may penetrate the entire thickness of the torus, or may have a depth that is part of the thickness of the torus. Accordingly, the slot 6 may penetrate the entire wall thickness of the base body or have a depth that is part of the wall thickness of the base body. The slot 16 can facilitate the process of stamping the connector blank 10a into the cable connector 1a. In an embodiment not shown, the connector blank 10a may have two or more slots 16.

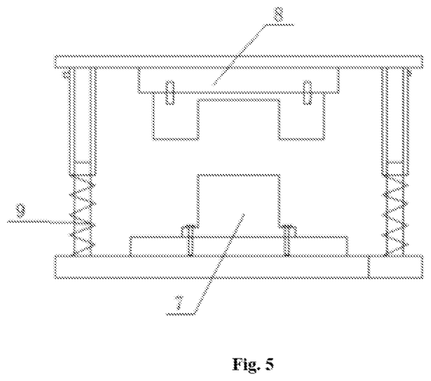

The cable connector 1 and the cable connector 1a can be manufactured with the help of the stamping die commonly used in practice as shown in FIG. 5, respectively. The stamping die can have a male die 7 and a female die 8, which can be separated from each other by the spring element 9, and can move towards each other until they are closed under the condition of overcoming the spring force of the spring element 9.

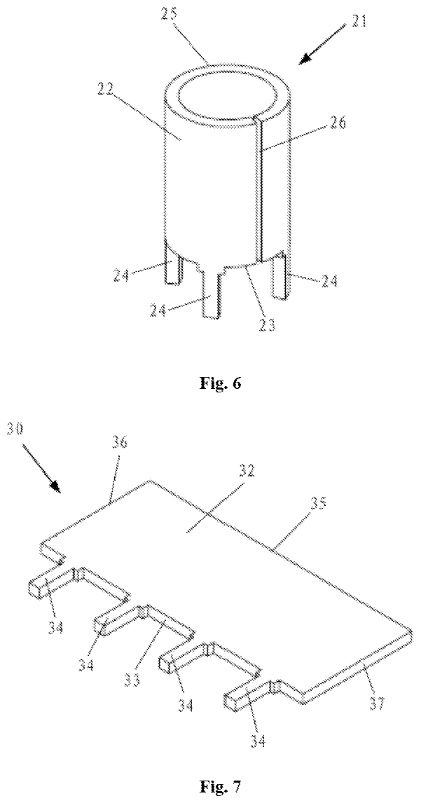

FIG. 6 is a perspective view of the cable connector 21 according to the third embodiment of the present disclosure, and FIG. 7 is a plan view of one embodiment of a connector blank 30 for manufacturing the cable connector 21. The cable connector 21 has a cylindrical base body 22 having a first end 23 and a second end 25. Four pins 24 extend from the first end 23 of the base body 22. Three of the pins are visible in FIG. 6, and the other pin is obscured and therefore invisible. The number of the pins 24 is exemplary and can be set according to actual needs. The base body 22 has a longitudinal slot 26 penetrating the entire wall thickness of the base body 22.

The cable connector 21 may be made of a connector blank 30 as shown in FIG. 7 by a forming process, and more specifically, by rolling. The connector blank 30 has a rectangular face 32 having a first longitudinal edge 33 and a second longitudinal edge 35 opposite to each other and a first transverse edge 36 and a second transverse edge 37 opposite to each other. Through the rolling process, the first transverse edge 36 and the second transverse edge 37 are bent to form the base body 22, and to form the longitudinal slot 26 of the base body 22 between the first transverse edge 36 and the second transverse edge 37; the four pins 34 extending from the first longitudinal edge 33 form the four pins 24 of the cable connector 21, the first longitudinal edge 33 forms the first end 23 of the cable connector 21 and surrounds the opening defining the first end 23, and the second longitudinal edge 35 forms the second end 25 of the cable connector 21 and surrounds the opening defining the second end 25 of the cable connector 21.

In an embodiment of another connector blank not shown, it differs from the connector blank 30 only in that the other connector blank does not have the pins 34, and forms a main body portion of a cable connector without pins 24 after stamping, and that the pins 24 can be subsequently produced in the first end of the main body portion by blanking, machining, or other processing methods.

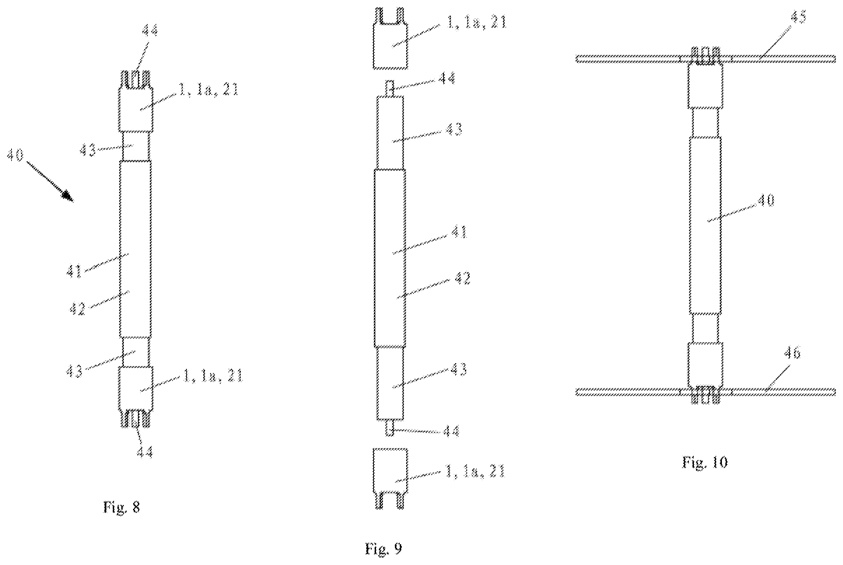

FIG. 8 is a schematic view of a cable assembly 40 in an assembled state according to an embodiment of the present disclosure, and FIG. 9 is an exploded view of the cable assembly 40. The cable assembly 40 includes a coaxial cable 41 and a cable connector arranged on two end sections of the coaxial cable 41. The two cable connectors may be cable connectors 1, 1a, and 21 according to any one of the embodiments herein. As known in practice, the coaxial cable 41 may include an inner conductor 44, a dielectric layer surrounding the inner conductor 44 on the circumference not shown in the drawing, an outer conductor 43 surrounding the dielectric layer on the circumference, and an insulating sheath 42 surrounding the outer conductor 43 on the circumference. The sheath 42 of the coaxial cable 41 is peeled on two end sections to expose the outer conductor section of the outer conductor 43. The cable connector is sleeved on the exposed outer conductor section from the second end, and is mechanically and electrically connected with the outer conductor section. The cable connector may be connected to the outer conductor section, for example, by crimping and/or welding.

FIG. 10 is a schematic view of a board assembly for a base station antenna according to an embodiment of the present disclosure. The board assembly may include a first circuit board 45 and a second circuit board 46 spaced apart from each other, which can be electrically connected to each other by means of at least one cable assembly 40, wherein each cable connector of the cable assembly 40 can be welded with the ground plane of the corresponding circuit board, and the inner conductor 44 of the coaxial cable 41 of the cable assembly 40 may be soldered with the conductor trace of the corresponding circuit board.

It will be understood that, the terminology used herein is for the purpose of describing particular aspects only and is not intended to be limiting of the disclosure. As used herein, the singular forms “a”, “an” and “the” are intended to include the plural forms as well, unless the context clearly indicates otherwise. It will be further understood that the terms “comprise” and “include” (and variants thereof), when used in this specification, specify the presence of stated operations, elements, and/or components, but do not preclude the presence or addition of one or more other operations, elements, components, and/or groups thereof. As used herein, the term “and/or” includes any and all combinations of one or more of the associated listed items. Like reference numbers signify like elements throughout the description of the figures.

The thicknesses of elements in the drawings may be exaggerated for the sake of clarity. Further, it will be understood that when an element is referred to as being “on,” “coupled to” or “connected to” another element, the element may be formed directly on, coupled to or connected to the other element, or there may be one or more intervening elements therebetween. In contrast, terms such as “directly on,” “directly coupled to” and “directly connected to,” when used herein, indicate that no intervening elements are present. Other words used to describe the relationship between elements should be interpreted in a like fashion (i.e., “between” versus “directly between”, “attached” versus “directly attached,” “adjacent” versus “directly adjacent”, etc.).

Terms such as “top,” “bottom,” “upper,” “lower,” “above,” “below,” and the like are used herein to describe the relationship of one element, layer or region to another element, layer or region as illustrated in the figures. It will be understood that these terms are intended to encompass different orientations of the device in addition to the orientation depicted in the figures.

It will be understood that, although the terms “first,” “second,” etc. may be used herein to describe various elements, these elements should not be limited by these terms. These terms are only used to distinguish one element from another. Thus, a first element could be termed a second element without departing from the teachings of the inventive concept.

It will also be appreciated that all example embodiments disclosed herein can be combined in any way.

Finally, it is to be noted that, the above-described embodiments are merely for understanding the present invention but not constitute a limit on the protection scope of the present invention. For those skilled in the art, modifications may be made on the basis of the above-described embodiments, and these modifications do not depart from the protection scope of the present invention.

1. A method for manufacturing a cable connector having a cylindrical base body and a plurality of pins extending from the first end of the base body, and being configured to be sleeved on the outer conductor of the coaxial cable from the second end opposite to the first end and mechanically and electrically connected with the outer conductor, wherein the method comprises:
providing a connector blank having a face for forming the base body, wherein the face has a first edge and a second edge, and the second edge is used to form the second end; and
constructing a complete cable connector by forming the connector blank, or constructing the main body portion of the cable connector except the pins and then forming the pins by subsequent processing of the main body portion.

2. The method according to claim 1, wherein a complete cable connector can be constructed by forming the connector blank, wherein the connector blank has pins protruding from the first edge.

3. The method according to claim 1, wherein:
the providing step comprises providing a connector blank having a torus for forming the base body, wherein the torus has an outer edge as a first edge and an inner edge as a second edge; and
the constructing step comprises forming the cable connector or the main body portion by stamping the connector blank.

4. The method according to claim 3, wherein the connector blank has a slot extending radially in the torus and opening toward the inner edge.

5. The method according to claim 1, wherein
the providing step comprises providing a connector blank having a rectangular face for forming the base body, wherein the rectangular faces has a first longitudinal edge as a first edge and a second longitudinal edge as a second edge, and a first transverse edge and a second transverse edge opposite each other; and
the constructing step comprises constructing the cable connector or the main body portion by stamping the connector blank, wherein the first transverse edge and the second transverse edge form a longitudinal slot of the base body.

6. A cable connector having a cylindrical base body and a plurality of pins protruding from the first end of the base body, wherein the cable connector is configured to be sleeved on an outer conductor of a coaxial cable having an inner conductor and the outer conductor from a second end opposite to the first end, and be mechanically and electrically connected with the outer conductor, and is characterized in that the complete cable connector is made from a connector blank by a forming process, or a main body portion of the cable connector except pins is formed from the connector blank by a forming process, and the pins are formed by subsequent processing of the main body portion; the connector blank has a face for forming the base body, the face has a first edge and a second edge, and the second edge is used for forming the second end.

7. The cable connector according to claim 6, wherein the complete cable connector is made by forming the connector blank, wherein a complete cable connector can be constructed by forming the connector blank, wherein the connector blank has pins protruding from the first edge.

8. The cable connector according to claim 6, wherein the connector blank has a torus for forming the base, the torus has an outer edge as a first edge and an inner edge as a second edge, and the cable connector or the main body portion is made by stamping the connector blank.

9. The cable connector according to claim 8, wherein the connector blank has a slot extending radially in the torus and opening toward the inner edge.

10. The cable connector according to claim 6, wherein the connector blank has a rectangular face for forming the base body, and the rectangular face has a first longitudinal edge as a first edge and a second longitudinal edge as a second edge, and a first transverse edge and a second transverse edge opposite each other, the cable connector or the main body portion is made by rolling the connector blank, wherein the first transverse edge and the second transverse edge form a longitudinal slot of the base body.

11. A cable assembly comprising:
a coaxial cable, wherein the coaxial cable includes:
an inner conductor;
a dielectric layer surrounding the inner conductor on the circumference;
an outer conductor surrounding the dielectric layer on the circumference; and
a sheath surrounding the outer conductor on circumference; and
a cable connector according to claim 6;
wherein the sheath of the coaxial cable is peeled on at least one end section to expose the outer conductor section of the outer conductor, and the cable connectors are sleeved on the exposed outer conductor section from a second end, and are mechanically and electrically connected with the outer conductor section.

12. The cable assembly according to claim 11, wherein the cable connector is connected with the outer conductor section by at least one of crimping and welding.

13. A circuit board assembly comprising a circuit board and a cable assembly according to claim 11, wherein the cable connector and the inner conductor are attached to the circuit board.
